(19) United States
(12) Patent Application Publication
(10) Pub. No.: US 2021/0096454 A1
(43) Pub. Date: Apr. 1, 2021

(54) PHOTOMASK HAVING MULTI-LAYERED TRANSFER PATTERNS

(71) Applicant: SK hynix Inc., Gyeonggi-do (KR)

(72) Inventor: Taejoong HA, Daejeon (KR)

(73) Assignee: SK hynix Inc.

(21) Appl. No.: 17/118,718

(22) Filed: Dec. 11, 2020

Related U.S. Application Data
(62) Division of application No. 15/914,166, filed on Mar. 7, 2018.

(30) Foreign Application Priority Data
Aug. 17, 2017 (KR) 10-2017-0104078

(51) Int. Cl. G03F 1/26; G03F 1/58; G03F 1/24

(52) U.S. Cl. CPC G03F 1/26; G03F 1/24; G03F 1/58

(57) ABSTRACT

A photomask includes a light transmission substrate and a phase shift pattern. The phase shift pattern includes a first phase shift pattern layer, a second phase shift pattern layer and a third phase shift pattern layer which are sequentially stacked on a surface of the light transmission substrate. A light transmittance of each of the first and third phase shift pattern layers is less than a light transmittance of the second phase shift pattern layer.

### CROSS-REFERENCE TO RELATED APPLICATIONS

This application is a division of U.S. patent application Ser. No. 15/914,166 filed on Mar. 7, 2018, which claims benefits of priority of Korean Patent Application No. 10-2017-0104078 filed on Aug. 17, 2017. The disclosure of each of the foregoing application is incorporated herein by reference in its entirety.

### BACKGROUND

### 1. Technical Field

Various embodiments of the present disclosure relate to photomasks and, more particularly, to photomasks having multi-layered transfer patterns.

### 2. Related Art

In general, a semiconductor device may include a plurality of patterns disposed on a semiconductor substrate. The patterns may be formed using a photolithography process and an etch process to realize active and/or passive elements on the semiconductor substrate. The photolithography process may be performed to form photoresist patterns. For example, the photolithography process may be performed by coating a photoresist material on a target layer to form a photoresist layer, by selectively exposing portions of the photoresist layer to light with a photomask, and by developing the exposed photoresist layer to form the photoresist patterns. The photoresist patterns may then be used as etch masks for patterning the target layer. As such, the photomask may be used to transfer predetermined pattern images onto the photoresist layer and may be generally comprised of a light transmission substrate and a plurality of transfer patterns. Generally, photomasks may be categorized as either permeable photomasks or reflective photomasks. The permeable photomasks may include binary photomasks and phase shift photomasks. The reflective photomasks may include extreme ultraviolet (EUV) photomasks.

In the photolithography process, light having a specific wavelength may be irradiated onto a photoresist layer on a wafer through a photomask. In case of the phase shift photomask, light generated by a light source may be irradiated onto the wafer through phase shift patterns and a light transmission substrate. In such a case, the light penetrating only the light transmission substrate maintains its original phase, while the light penetrating the phase shift pattern and the light transmission substrate may obtain a phase which is opposite to its original phase. In case of the reflective photomask, light generated by a light source is reflected by a multi-layered reflection pattern of the reflective photomask toward the wafer. In such a case, almost all of the light irradiated onto a light absorption pattern of the reflective photomask may be absorbed into the light absorption pattern. For both the phase shift photomask and the reflective photomask, the light generated by the light source may be obliquely irradiated onto a surface of a transfer pattern (e.g., the phase shift pattern or the multi-layered reflection pattern) using an off-axis illumination system. In such a case, the light obliquely irradiated onto an edge of the transfer pattern may be undesirably absorbed into the phase shift pattern or transmitted through a multi-layered reflection pattern. This may be because a thickness of the edge of the transfer pattern in a travelling direction of the oblique light is less than a total thickness of a central portion of the transfer pattern. That is, the oblique light penetrating the edge of the phase shift pattern may have a different phase from the oblique light penetrating the central portion of the phase shift pattern, and the oblique light reflected by the edge of the multi-layered reflection pattern may have a different intensity from the oblique light reflected by the central portion of the multi-layered reflection pattern. As a result, the pattern accuracy of the photolithography process may be degraded.

### SUMMARY

According to an embodiment, a photomask includes a light transmission substrate and a plurality of phase shift patterns. Each phase shift pattern includes a first phase shift pattern layer, a second phase shift pattern layer and a third phase shift pattern layer which are sequentially stacked on a surface of the light transmission substrate. A light transmittance of each of the first and third phase shift pattern layers is less than a light transmittance of the second phase shift pattern layer.

According to another embodiment, a photomask includes a substrate, a multi-layered reflection layer and an absorption pattern. The multi-layered reflection layer is disposed on a surface of the substrate. The absorption pattern includes a first absorption pattern layer and a second absorption pattern layer which are sequentially stacked on a surface of the multi-layered reflection layer opposite to the substrate. A light absorptiveness of the second absorption pattern layer is higher than a light absorptiveness of the first absorption pattern layer.

### BRIEF DESCRIPTION OF THE DRAWINGS

Various embodiments of the present disclosure will become more apparent in view of the attached drawings and accompanying detailed description, in which:

FIG. 1 is a cross-sectional view illustrating a conventional phase shift photomask;

FIG. 2 is a cross-sectional view illustrating a phase shift photomask according to an embodiment of the present disclosure;

FIG. 3 is a cross-sectional view illustrating a function of the phase shift photomask shown in FIG. 2;

FIG. 4 is a cross-sectional view illustrating a reflective photomask according to an embodiment of the present disclosure; and

FIG. 5 is a cross-sectional view illustrating a function of the reflective photomask shown in FIG. 4.

### DETAILED DESCRIPTION OF THE EMBODIMENTS

In the following description of exemplary embodiments of the present invention, it will be understood that the terms “first” and “second” are intended to identify an element, but not used to define only the element itself or to mean a particular sequence. In addition, when an element is referred to as being located “on”, “over”, “above”, “under” or “beneath” another element, it is intended to mean relative position relationship, but not used to limit certain cases that the element directly contacts the other element, or at least one intervening element is present therebetween. Accordingly, the terms such as “on”, “over”, “above”, “under”, “beneath”, “below” and the like that are used herein are for the purpose of describing particular embodiments only and are not intended to limit the scope of the present disclosure. Further, when a first element is referred to as being “connected” or “coupled” to a second element, the first element may be operatively or physically connected or coupled to the second element directly, or indirectly. The connection or coupling may be for example at least one of an electrical or mechanical connection or coupling.

It is further noted that in the following description well known structures and functions are not described in order to avoid obscuring the description of the invention. Moreover, it should be understood that the drawings are simplified schematics and that they are not drawn in scale in order to emphasize the elements of the inventions. I should also be understood that an element described in conjunction with one embodiment, may also be employed with another embodiment.

Various embodiments of the present invention which are directed to photomasks having multi-layered transfer patterns will be described in conjunction with the following drawings. It is noted that when the same numerals are used in different drawings they represent the same elements.

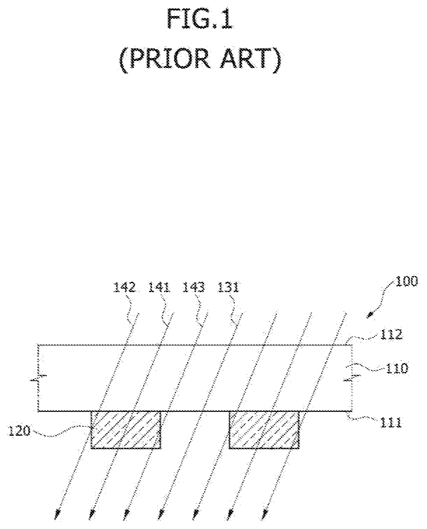

FIG. 1 is a cross-sectional view illustrating a typical conventional phase shift photomask 100. Referring FIG. 1, the conventional phase shift photomask 100 may include a light transmission substrate 110 and phase shift patterns 120. The light transmission substrate 110 may be comprised of a transparent material, for example, a quartz material. The light transmission substrate 110 may have a front surface 111 and a backside surface 112 which are opposite to each other. The phase shift patterns 120 may be disposed on the front surface 111 of the light transmission substrate 110. The light transmission substrate 110 may be exposed by spaces between the phase shift patterns 120. The phase shift patterns 120 may be formed of a material that changes the phase of a light passing through the phase shift patterns 120. For example, the phase shift patterns 120 may be formed of a chrome oxide (CrOₓ) material or a molybdenum silicide (MoSi2) material. Alternatively, the phase shift patterns 120 may be formed of a combination material of a silicon nitride (SiN) material, a silicon oxynitride (SiON) material, a ruthenium (Ru) material, a tantalum (Ta) material and a silicon oxide (SiO₂) material. The phase shift patterns 120 may have a light transmittance of approximately 5% to approximately 90%. For example, the phase shift patterns 120 may have a light transmittance of approximately 20%. A transmitted light passing through any one of the phase shift patterns 120 may have a phase difference of 180 degrees as compared with an incident light irradiated onto the phase shift patterns 120.

In the event that an exposure process is performed using the general phase shift photomask 100, the general phase shift photomask 100 may be disposed between a light source (not shown) of an exposure apparatus and a wafer (not shown) loaded into the exposure apparatus. An illumination system (not shown) may be disposed between the light source and the phase shift photomask 100 loaded into the exposure apparatus. An off-axis illumination system having an improved resolution and an improved depth of focus (DOF) may be used as the illumination system. The off-axis illumination system may be an annular illumination system, a dipole illumination system or a quadrupole illumination system. The wafer may be provided to have a target material layer and a photoresist layer coated on the target material layer. The phase shift photomask 100 may be disposed so that the phase shift patterns 120 face the photoresist layer of the wafer. The light outputted from the light source may pass through the off-axis illumination system and may be obliquely irradiated onto the backside surface 112 of the phase shift photomask 100 to pass through the light transmission substrate 110. A portion of an oblique incident light passing through the light transmission substrate 110 may penetrate the phase shift patterns 120 to reach the wafer, and the other portion of the oblique incident light passing through the light transmission substrate 110 may directly reach the wafer without penetrating the phase shift patterns 120. The oblique incident light irradiated onto the backside surface 112 of the phase shift photomask 100 may travel along an oblique light path even while the oblique incident light passes through the phase shift photomask 100.

Since a refractive index of the light transmission substrate 110 is different from a refractive index of the phase shift patterns 120, a travelling direction of an oblique incident light may change at an interface between the light transmission substrate 110 and the phase shift pattern 120 if the oblique incident light penetrates the light transmission substrate 110 or the phase shift pattern 120 to reach the interface between the light transmission substrate 110 and the phase shift pattern 120. However, for the purpose of ease and convenience in explanation, it is assumed that the oblique incident light travels along the same direction in the light transmission substrate 110 and the phase shift pattern 120. That is, an inventive concept of the present disclosure for suppressing a pattern transfer error due to a phase deviation of the oblique incident light may be equally applicable to all of the following embodiments, even though a travelling direction of the oblique incident light changes at the interface between the light transmission substrate 110 and the phase shift pattern 120 due to a difference between the refractive indexes of the light transmission substrate 110 and the phase shift pattern 120.

In FIG. 1, an oblique incident light 131 penetrating only the light transmission substrate 110 may be irradiated onto the wafer (not shown) without any change of a phase of the oblique incident light 131. On the contrary, phases of oblique incident lights 141, 142 and 143 penetrating both of the light transmission substrate 110 and the phase shift pattern 120 may be shifted as compared with an original phase of the oblique incident lights 141, 142 and 143, and the oblique incident lights 141, 142 and 143 having the shifted phases may be irradiated onto the wafer. In such a case, a light transmittance of the phase shift pattern 120 may be different according to a thickness (in a travelling direction of the oblique incident light 141, 142 or 143) of a portion of the phase shift pattern 120 through which the oblique incident light 141, 142 or 143 passes, and an angle corresponding to the shifted phase of the oblique incident light 141, 142 or 143 may also be determined by a thickness of a portion of the phase shift pattern 120 through which the oblique incident light 141, 142 or 143 passes. For example, the oblique incident light 141 may fully pass through a central portion of the phase shift pattern 120 with a light transmittance of approximately 20% to have a shifted phase angle of approximately 180 degrees, and each of the oblique incident lights 142 and 143 may partially pass through only an edge corner portion of the phase shift pattern 120 with a light transmittance of approximately 75% to have a shifted phase angle of approximately 45 degrees. As such, if the oblique incident lights 141, 142 and 143 are irradiated onto the phase shift photomask 100 using an off-axis illumination system, the oblique incident lights 141, 142 and 143 passing through the phase shift pattern 120 may have shifted phase angles which are non-uniform. This may degrade the accuracy of the patterns which are formed on the wafer. In particular, since a light transmittance of the edge corner portions of the phase shift pattern 120 through which the oblique incident lights 142 and 142 pass is higher than a light transmittance of the central portion of the phase shift pattern 120 through which the oblique incident light 141 passes, the shifted phase angles of the oblique incident lights 141, 142 and 143 may be non-uniform to cause degradation of accuracy of the patterns which are formed on the wafer.

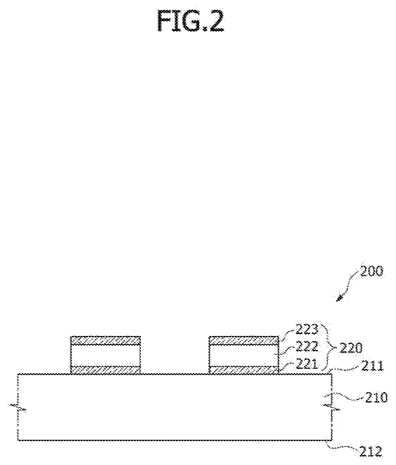

FIG. 2 is a cross-sectional view illustrating a phase shift photomask 200 according to an embodiment of the present disclosure. Referring to FIG. 2, the phase shift photomask 200 may include a light transmission substrate 210 and phase shift patterns 220. In an embodiment, the light transmission substrate 210 may be comprised of a transparent material, for example, a quartz material. The light transmission substrate 210 may have a front surface 211 and a backside surface 212 which are opposite to each other. The phase shift patterns 220 may be disposed on the front surface 211 of the light transmission substrate 210. The light transmission substrate 210 may be exposed by spaces between the phase shift patterns 220. The phase shift patterns 220 may act as transfer patterns. That is, images of the phase shift patterns 220 may be transferred to a photoresist layer coated on a wafer (not shown) by a photolithography process.

Each of the phase shift patterns 220 may have a multi-layered structure including a first phase shift pattern layer 221, a second phase shift pattern layer 222 and a third phase shift pattern layer 223 which are sequentially stacked. In an embodiment, the second phase shift pattern layer 222 may be comprised of a different material from the first and third phase shift pattern layers 221 and 223. The first and third phase shift pattern layers 221 and 223 may be comprised of the same material. In an embodiment, each of the first and third phase shift pattern layers 221 and 223 may include at least one of a molybdenum (Mo) material, a silicon (Si) material, a chrome (Cr) material, a tantalum (Ta) material, a ruthenium (Ru) material, an aluminum (Al) material, a copper (Cu) material, a cobalt (Co) material and a nickel (Ni) material as main components of the first or third phase shift pattern layer 221 or 223. Similarly, the second phase shift pattern layer 222 may also include at least one of a molybdenum (Mo) material, a silicon (Si) material, a chrome (Cr) material, a tantalum (Ta) material, a ruthenium (Ru) material, an aluminum (Al) material, a copper (Cu) material, a cobalt (Co) material and a nickel (Ni) material as main components of the second phase shift pattern layer 222. In such a case, a light transmittance of each of the first, second and third phase shift pattern layers 221, 222 and 223 may be controlled by appropriately adjusting a weight ratio of the main components of the first, second or third phase shift pattern layer 221, 222 or 223. In addition, a light transmittance of each of the first, second and third phase shift pattern layers 221, 222 and 223 may also be controlled by appropriately injecting oxygen atoms and/or nitrogen atoms into the first, second or third phase shift pattern layer 221, 222 or 223. In an embodiment, the second phase shift pattern layer 222 may have a thickness which is greater than a thickness of the first and third phase shift pattern layers 221 and 223. The first and third phase shift pattern layers 221 and 223 may have the same thickness.

Each of the first and third phase shift pattern layers 221 and 223 should have a light transmittance which is less than a light transmittance of the second phase shift pattern layer 222 regardless of the specific materials or thicknesses of the first, second and third phase shift pattern layers 221, 222 and 223 which may vary design. In an embodiment, the first and third phase shift pattern layers 221 and 223 may have substantially the same light transmittance. For example, the second phase shift pattern layer 222 may have a light transmittance of approximately 80%, and each of the first and third phase shift pattern layers 221 and 223 may have a light transmittance of approximately 50%.

The first phase shift pattern layer 221 may shift a phase of light by a first phase shift angle. The second phase shift pattern layer 222 may shift a phase of light by a second phase shift angle. The third phase shift pattern layer 223 may shift a phase of light by a third phase shift angle. A sum of the first, second and third phase shift angles may be 180 degrees. The second phase shift angle may be greater than any one of the first and third phase shift angles. The first and third phase shift angles may be substantially equal to each other. In an embodiment, the second phase shift angle may be substantially 90 degrees, and each of the first and third phase shift angles may be substantially 45 degrees.

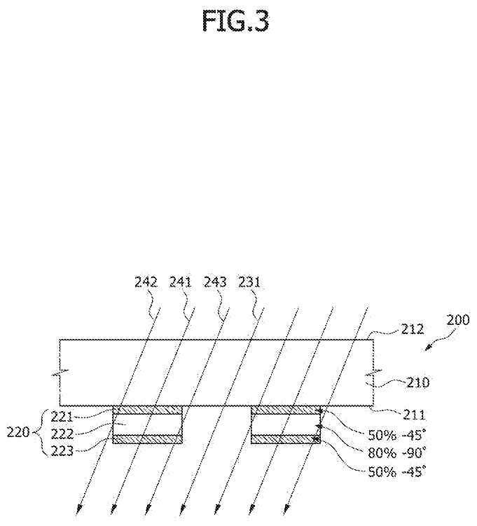

FIG. 3 is a cross-sectional view illustrating a function of the phase shift photomask 200 shown in FIG. 2. In FIG. 3, the same reference numerals as used in FIG. 2 denote the same elements. Referring to FIG. 3, in the event that an exposure process is performed using the phase shift photomask 200, the phase shift photomask 200 may be disposed between a light source and a wafer which are located in an exposure apparatus. An illumination system (not shown) may be disposed between the light source and the phase shift photomask 200 loaded into the exposure apparatus. An off-axis illumination system having an improved resolution and an improved depth of focus (DOF) may be used as the illumination system. In an embodiment, the off-axis illumination system may be an annular illumination system, a dipole illumination system or a quadrupole illumination system. The wafer may be provided to have a target material layer and a photoresist layer coated on the target material layer. The phase shift photomask 200 may be disposed so that the phase shift patterns 220 face the photoresist layer of the wafer. The light outputted from the light source may pass through the off-axis illumination system and may be obliquely irradiated onto the backside surface 212 of the light transmission substrate 210 of the phase shift photomask 200 to pass through the light transmission substrate 210. A portion of an oblique incident light passing through the light transmission substrate 210 may penetrate the phase shift patterns 220 to reach the wafer, and the other portion of the oblique incident light passing through the light transmission substrate 210 may directly reach the wafer without penetrating the phase shift patterns 220. The oblique incident light irradiated onto the backside surface 212 of the light transmission substrate 210 may travel along an oblique light path even while the oblique incident light passes through the phase shift photomask 200.

In the present embodiment, it is assumed that each of the first and third phase shift pattern layers 221 and 223 has a light transmittance of 50% and a phase shift angle of 45 degrees and the second phase shift pattern layer 222 has a light transmittance of 80% and a phase shift angle of 90 degrees. In FIG. 3, an oblique incident light 231 penetrating only the light transmission substrate 210 may be irradiated onto the wafer (not shown) without any change of a phase of the oblique incident light 231. On the contrary, phases of oblique incident lights 241, 242 and 243 penetrating both of the light transmission substrate 210 and the phase shift pattern 220 may be shifted as compared with an original phase of the oblique incident lights 241, 242 and 243, and the oblique incident lights 241, 242 and 243 having the shifted phases may be irradiated onto the wafer.

The oblique incident light 241 may pass through all of the first, second and third phase shift pattern layers 221, 222 and 223 with a light transmittance of approximately 20%. Specifically, approximately 50% of the oblique incident light 241 penetrating the light transmission substrate 210 may pass through the first phase shift pattern layer 221, and approximately 80% of the oblique incident light 241 penetrating the first phase shift pattern layer 221 may pass through the second phase shift pattern layer 222. Thus, the first and second phase shift pattern layers 221 and 222 may transmit approximately 40% of the oblique incident light 241 penetrating the light transmission substrate 210. The third phase shift pattern layer 223 may transmit approximately 50% of the oblique incident light 241 penetrating the first and second phase shift pattern layers 221 and 222. Accordingly, approximately 20% of the oblique incident light 241 penetrating the light transmission substrate 210 may pass through the first, second and third phase shift pattern layers 221, 222 and 223.

A phase of the oblique incident light 241 passing through all of the first, second and third phase shift pattern layers 221, 222 and 223 may be shifted by 180 degrees to be inverted as compared with an original phase of the oblique incident light 241 irradiated onto the backside surface 212 of the light transmission substrate 210. A phase of the oblique incident light 241 penetrating the first phase shift pattern layer 221 may be shifted by 45 degrees as compared with an original phase of the oblique incident light 241 irradiated onto the backside surface 212 of the light transmission substrate 210. Since a phase of the oblique incident light 241 penetrating the second phase shift pattern layer 222 is shifted by 90 degrees, a phase of the oblique incident light 241 penetrating both of the first and second phase shift pattern layers 221 and 222 may be shifted by 135 degrees. Since a phase of the oblique incident light 241 penetrating the third phase shift pattern layer 223 is shifted by 45 degrees, a phase of the oblique incident light 241 penetrating all of the first, second and third phase shift pattern layers 221, 222 and 223 may be shifted by 180 degrees to be inverted as compared with an original phase of the oblique incident light 241 irradiated onto the backside surface 212 of the light transmission substrate 210.

The oblique incident light 242 penetrating the light transmission substrate 210 and an edge corner portion of the phase shift pattern 220 adjacent to the light transmission substrate 210 may fully pass through the first phase shift pattern layer 221 and may pass through only a portion of the second phase shift pattern layer 222 having a thickness which is less than a total thickness of the second phase shift pattern layer 222. Thus, a light transmittance and a phase shift of the oblique incident light 242 may be dominantly influenced by the first phase shift pattern layer 221. Accordingly, the oblique incident light 242 penetrating the edge corner portion of the phase shift pattern 220, that is, the first phase shift pattern layer 221 may have an amount of approximately 50% of the oblique incident light 242 irradiated onto the backside surface 212 of the light transmission substrate 210, and a phase of the oblique incident light 242 penetrating the first phase shift pattern layer 221 may be shifted by approximately 45 degrees. In such a case, although the oblique incident light 242 penetrating the first phase shift pattern layer 221 has a shifted phase as compared with the oblique incident light 241 penetrating a central portion of the phase shift pattern 220, the shifted phase of the oblique incident light 242 may be less than the shifted phase of the oblique incident light 142 illustrated in FIG. 1. This is because the oblique incident light 142 passes through an edge corner portion of the phase shift pattern (120 of FIG. 1) with a light transmittance of approximately 75% to approximately 80% while the oblique incident light 242 passes through an edge corner portion of the phase shift pattern 220 with a light transmittance of approximately 50%. Thus, a pattern resolution obtained with the phase shift photomask 200 may be improved as compared with a pattern resolution obtained with the phase shift photomask 100 illustrated in FIG. 1.

Similarly, the oblique incident light 243 penetrating the light transmission substrate 210 and an edge corner portion of the phase shift pattern 220 opposite to the light transmission substrate 210 may fully pass through the third phase shift pattern layer 223 and may pass through only a portion of the second phase shift pattern layer 222 having a thickness which is less than a total thickness of the second phase shift pattern layer 222. Thus, a light transmittance and a phase shift of the oblique incident light 243 may be dominantly influenced by the third phase shift pattern layer 223. Accordingly, the oblique incident light 243 penetrating the edge corner portion of the phase shift pattern 220, that is, the third phase shift pattern layer 223 may have an amount of approximately 50% of the oblique incident light 243 irradiated onto the backside surface 212 of the light transmission substrate 210, and a phase of the oblique incident light 243 penetrating the third phase shift pattern layer 223 may be shifted by approximately 45 degrees. Even in such a case, although the oblique incident light 243 penetrating the third phase shift pattern layer 223 has a shifted phase as compared with the oblique incident light 241 penetrating a central portion of the phase shift pattern 220, the shifted phase of the oblique incident light 243 may be less than the shifted phase of the oblique incident light 143 illustrated in FIG. 1. This is because the oblique incident light 143 passes through an edge corner portion of the phase shift pattern (120 of FIG. 1) with a light transmittance of approximately 75% to approximately 80% while the oblique incident light 243 passes through an edge corner portion of the phase shift pattern 220 with a light transmittance of approximately 50%. Thus, a pattern resolution obtained with the phase shift photomask 200 may be improved as compared with a pattern resolution obtained with the phase shift photomask 100 illustrated in FIG. 1.

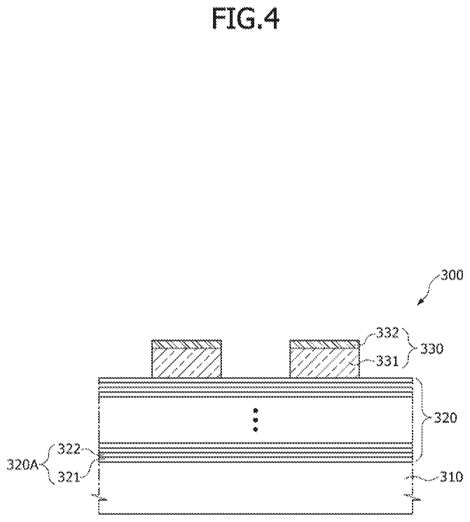

FIG. 4 is a cross-sectional view illustrating a reflective photomask 300 according to an embodiment of the present disclosure. Referring to FIG. 4, the reflective photomask 300 may be configured to include a multi-layered reflection layer 320 disposed on a substrate 310 and absorption patterns 330 disposed on a surface of the multi-layered reflection layer 320 opposite to the substrate 310. The multi-layered reflection layer 320 may be exposed by spaces between the absorption patterns 330. The absorption patterns 330 may act as transfer patterns. That is, images of the absorption patterns 330 may be transferred to a photoresist layer coated on a wafer (not shown) by a photolithography process. In such a case, an extreme ultraviolet (EUV) ray having a wavelength of approximately 13.5 nanometers may be used as a light generated by a light source in a photolithography process.

The substrate 310 may be any one of a light transmission substrate and an opaque substrate. Preferably, the substrate 310 may be comprised of a low thermal extension material (LTEM) to prevent any substantial volume expansion of the substrate 310 due to the EUV light. In general, when EUV light is absorbed into a substrate, the high energy of the EUV ray is converted into thermal energy that raises the temperature of the substrate and could increase the volume of the substrate which may in turn cause a pattern position change or error. Thus, it may be necessary that the substrate 310 is comprised of a material having a low thermal expansion coefficient (TEC) in order to suppress an increase of the volume of the substrate 310 due to a rise of its temperature due to a partial absorption of the EUV light. In an embodiment, the substrate 310 may include a material exhibiting a pattern position error of approximately ±0.05 ppm/° C. in a temperature range of zero degrees to 50 degrees.

The present invention may further require that the substrate 310 has an excellent surface flatness. In an embodiment, a front surface of the substrate 310 may have a flatness which is equal to or less than approximately 50 nanometers, and a backside surface of the substrate 310 may have a flatness which is equal to or less than approximately 500 nanometers. In addition, EUV light reflectivity of the substrate 310 may be substantially zero to prevent the EUV light from being reflected by a border region between a transfer pattern region and a frame region of the reflective photomask 300. The frame region surrounds the transfer pattern region and don't have the transfer patterns.

The multi-layered reflection layer 320 may have a stack structure including a plurality of reflection pairs 320A which are stacked on the substrate 310, and each reflection pair 320A may include a first reflection layer 321 and a second reflection layer 322 that have different diffraction coefficients. In an embodiment, one of the first and second reflection layers 321 and 322 may be a molybdenum (Mo) layer, and the other layer may be a silicon layer. In such a case, a thickness of the molybdenum (Mo) layer and a thickness of the silicon (Si) layer may be optimized to minimize the absorption of the EUV ray and to maximize the dispersion of the EUV ray. In an embodiment, the molybdenum (Mo) layer may have a thickness of approximately 4 nanometers, and the silicon (Si) layer may have a thickness of approximately 3 nanometers. A total thickness of the multi-layered reflection layer 320 may be within the range of approximately 280 nanometers to approximately 350 nanometers. The number of the reflection pairs 320A constituting the multi-layered reflection layer 320 may be within the range of approximately 40 to approximately 50. If the number of the reflection pairs 320A is less than 40, the EUV ray reflectivity of the reflection layer 320 may be remarkably reduced. If the number of the reflection pairs 320A is greater than 50, an increasing rate of the EUV ray reflectivity of the reflection layer 320 may be low and a deposition time of the multi-layered reflection layer 320 may increase to cause the increase of a defect density in the multi-layered reflection layer 320.

Each of the absorption patterns 330 may include a metal layer which is cable of absorbing the EUV ray when an exposure process is performed using the reflective photomask 300. Although not shown in the drawings, a buffer layer may be additionally disposed between each absorption pattern 330 and the multi-layered reflection layer 320. The buffer layer may be disposed to protect the multi-layered reflection layer 320 during an etch process for forming the absorption patterns 330. A capping layer (not shown) may be additionally disposed between each absorption pattern 330 and the multi-layered reflection layer 320. The capping layer may be disposed to protect the multi-layered reflection layer 320. Specifically, the capping layer may be formed of a material having a relatively low EUV ray absorptiveness to suppress the degradation of the EUV ray reflectivity of the multi-layered reflection layer 320. In an embodiment, the capping layer may be comprised of a silicon (Si) layer or a ruthenium (Ru) layer that has a thickness of approximately 1 nanometer to approximately 2.5 nanometers. Each of the absorption patterns 330 may have a stack structure including a first absorption pattern layer 331 and a second absorption pattern layer 332 which are sequentially stacked on the multi-layered reflection layer 320. The first absorption pattern layer 331 may have a thickness which is greater than a thickness of the second absorption pattern layer 332. The second absorption pattern layer 332 may have a light absorptiveness which is greater than a light absorptiveness of the first absorption pattern layer 331.

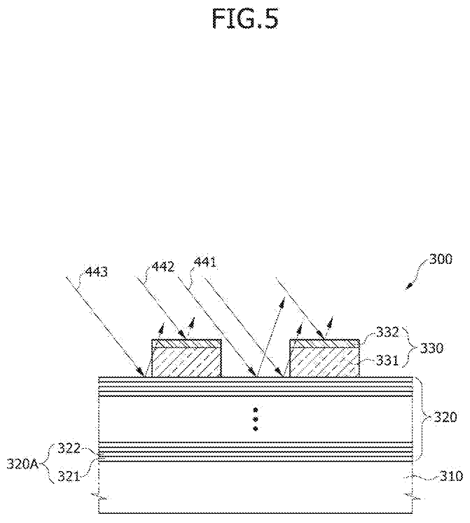

FIG. 5 is a cross-sectional view illustrating a function of the reflective photomask 300 shown in FIG. 4. In FIG. 5, the same reference numerals as used in FIG. 4 denote the same elements. Referring to FIG. 5, in the event that an exposure process is performed using the reflective photomask 300, an oblique incident light 441 irradiated onto the multi-layered reflection layer 320 may reflect from the multi-layered reflection layer 320 to travel toward a wafer (not shown) without passing through any of the absorption patterns 330. In such a case, an amount of the reflected light of the oblique incident light 441 may be determined according to a reflectivity of the multi-layered reflection layer 320. Most of an oblique incident light 442 irradiated onto the second absorption pattern layers 332 may be absorbed into the absorption patterns 330. Meanwhile, an oblique incident light 443 irradiated onto the multi-layered reflection layer 320 may reflect from the multi-layered reflection layer 320 and may pass through an upper corner portion of the absorption pattern 330 to travel toward the wafer. If the second absorption pattern layers 332 has a low light absorptiveness which is equal to a light absorptiveness of the first absorption pattern layer 331, an intensity of the reflected light of the oblique incident light 443 passing through the upper corner portion of the absorption pattern 330 may be clearly higher than an intensity of a reflected light of the oblique incident light 442. In such a case, a resolution of images of the absorption patterns 330 transferred to the wafer may be degraded. However, according to the present embodiment, the second absorption pattern layers 332 may have a light absorptiveness which is higher than a light absorptiveness of the first absorption pattern layer 331. In such a case, the second absorption pattern layers 332 may dominantly absorb both of the oblique incident light 442 and the reflected light of the oblique incident light 443. Thus, a resolution of images of the absorption patterns 330 transferred to the wafer may be improved.

The embodiments of the present disclosure have been disclosed above for illustrative purposes. Those of ordinary skill in the art will appreciate that various modifications, additions, and substitutions are possible, without departing from the scope and spirit of the present disclosure as disclosed in the accompanying claims.

What is claimed is:

1. A photomask comprising:
a substrate;
a multi-layered reflection layer disposed on a surface of the substrate; and
an absorption pattern including a first absorption pattern layer and a second absorption pattern layer which are sequentially stacked on a surface of the multi-layered reflection layer opposite to the substrate,
wherein a light absorptiveness of the second absorption pattern layer is higher than a light absorptiveness of the first absorption pattern layer.

2. The photomask of claim 1, wherein the first absorption pattern layer has a thickness which is greater than a thickness of the second absorption pattern layer.

3. The photomask of claim 1,
wherein the multi-layered reflection layer includes a plurality of reflection pairs which are stacked on the substrate; and
wherein each reflection pair includes a first reflection layer and a second reflection layer that have different diffraction coefficients.
